(19) United States
(12) Patent Application Publication
(10) Pub. No.: US 2025/0393222 A1
(43) Pub. Date: Dec. 25, 2025

(54) SEMICONDUCTOR DEVICE HEAT SPREADER AND METHOD

(71) Applicant: Micron Technology, Inc., Boise, ID (US)

(72) Inventors: Wei Zhou, Boise, ID (US); Kunal R. Parekh, Boise, ID (US)

(21) Appl. No.: 19/243,400

(22) Filed: Jun. 19, 2025

Related U.S. Application Data
(60) Provisional application No. 63/661,660, filed on Jun. 19, 2024.

(51) Int. Cl. H10B 80/00; H01L 23/00; H01L 25/00; H01L 25/065; H01L 25/18

(52) U.S. Cl. CPC H10B 80/00; H01L 24/08; H01L 24/80; H01L 25/0657; H01L 25/18; H01L 25/50; H01L 2224/08145; H01L 2224/80006; H01L 2224/80895; H01L 2224/80896; H01L 2225/06541; H01L 2225/06589; H01L 2924/1431; H01L 2924/1436

(57) ABSTRACT

Example semiconductor devices and methods include a heat spreader die and a heat conducting layer adjacent to an active surface a die. The heat conducting layer provides hot spot heat spreading in a lateral direction within the heat conducting layer. Selected examples of the heat spreader die provide additional mechanical stiffness and add strength to the semiconductor device.

### PRIORITY APPLICATION

This application claims the benefit of priority to U.S. Provisional Application Ser. No. 63/661,660, filed Jun. 19, 2024, which is incorporated herein by reference in its entirety.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to transistor structures in complementary metal oxide semiconductor (CMOS) devices and manufacture.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2A illustrates selected components in a wafer level process in accordance with some example embodiments.

FIG. 2B illustrates a subsequent stage of manufacture from FIG. 2A of selected components in a wafer level process in accordance with some example embodiments.

FIG. 3A illustrates selected components of a semiconductor device in a stage of manufacture in accordance with some example embodiments.

FIG. 3B illustrates selected components of a semiconductor device in another stage of manufacture in accordance with some example embodiments.

FIG. 3C illustrates selected components of a semiconductor device in another stage of manufacture in accordance with some example embodiments.

FIG. 3D illustrates selected components of a semiconductor device in another stage of manufacture in accordance with some example embodiments.

FIG. 3E illustrates selected components of a semiconductor device in another stage of manufacture in accordance with some example embodiments.

FIG. 3F illustrates selected components of a semiconductor device in another stage of manufacture in accordance with some example embodiments.

FIG. 4A illustrates selected components of a semiconductor device in a stage of manufacture in accordance with some example embodiments.

FIG. 4B illustrates selected components of a semiconductor device in another stage of manufacture in accordance with some example embodiments.

FIG. 4C illustrates selected components of a semiconductor device in another stage of manufacture in accordance with some example embodiments.

FIG. 4D illustrates selected components of a semiconductor device in another stage of manufacture in accordance with some example embodiments.

FIG. 4E illustrates selected components of a semiconductor device in another stage of manufacture in accordance with some example embodiments.

FIG. 5 illustrates an example method flow diagram in accordance with other example embodiments.

FIG. 6 illustrates an example block diagram of an information handling system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

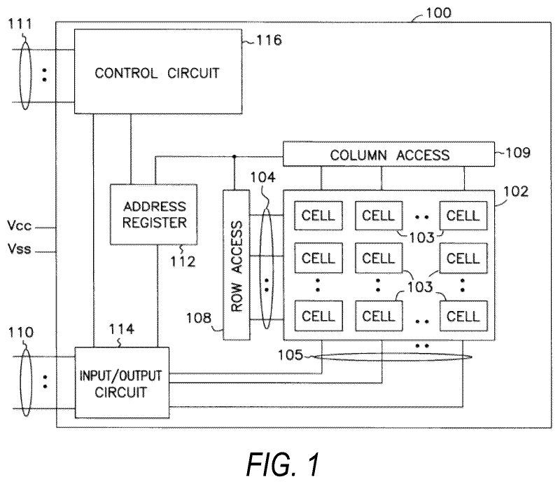

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103.

Memory cells 103 and other circuits 114, 116, etc. may be included in semiconductor chips or circuits that are included in devices described in other figures below. In one example, memory arrays 102 include RAM storage, and peripheral circuits such as circuits 114, 116, 108, 109, etc. may include transistors as described in more detail other figures below. In one example, memory arrays 102 include NAND storage.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of the memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that can store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art will recognize that memory device 100 may include other elements, several of which are not shown in FIG. 1, so as not to obscure the example embodiments described herein.

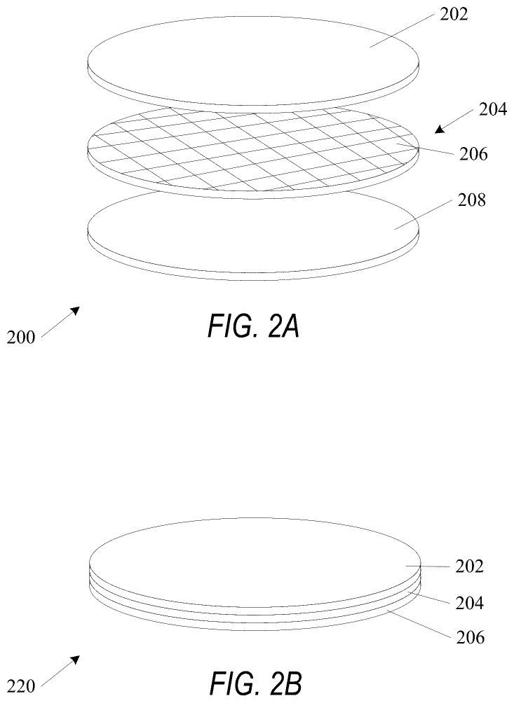

Selected examples of devices produced in the present disclosure are formed using wafer level processes. FIG. 2A shows a stage 200 of a wafer level manufacturing process. One advantage of wafer level processing includes ease of handling larger wafers. Another advantage of wafer level processing includes faster, higher volume production with an ability to produce large numbers of individual chips at once.

In FIG. 2A, a first wafer 202 is coupled to a second wafer 204. In the example of FIG. 2A, the first wafer 202 includes a logic wafer with a number of logic dies (not shown-facing downward in FIG. 2A), and the second wafer 204 includes a device wafer with a number of semiconductor device dies 206. In one example, the number of semiconductor device dies 206 include memory dies, although the invention is not so limited. A third wafer 208 is also shown in FIG. 2A. In one example, the third wafer 208 includes a carrier wafer as described in more detail below.

FIG. 2B shows a subsequent stage of manufacture in the wafer level manufacturing process. After the stage shown in FIG. 2A, the first wafer 202, the second wafer 204, and the third wafer 208 are coupled together to form combined wafer 220. A number of coupling methods are within the scope of the invention. As described in more detail below, in one example, hybrid bonding provides electrical connections between the first wafer 202 and the second wafer 204. In one example, fusion bonding provides electrical connections between the first wafer 202 and the second wafer 204. Although hybrid bonding and fusion bonding are used as examples, the invention is not so limited. Solder bonding is also possible to provide electrical connections between the first wafer 202 and the second wafer 204. Advantages of hybrid bonding and fusion bonding include lower temperature formation of electrical connection. Low temperature is beneficial because it reduces damage to previously formed structures in wafers.

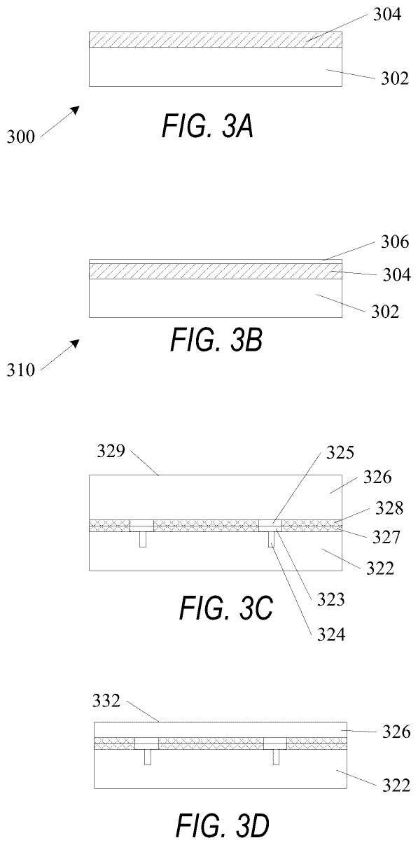

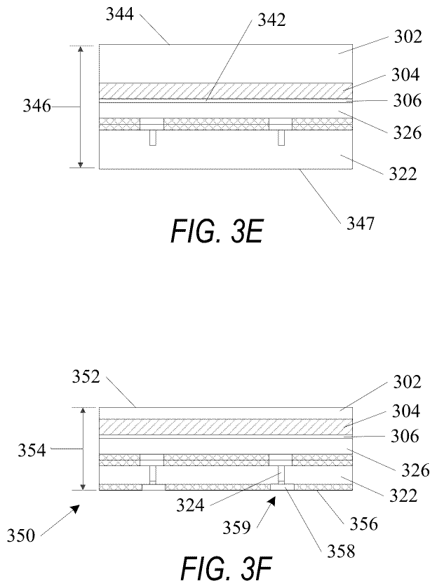

FIG. 3A shows a portion 300 of a die similar to third wafer 208 from FIGS. 2A-2B. The portion 300 may illustrate a singulated portion from a wafer, or the portion 300 may illustrate a whole continuous wafer in a stage of manufacture of a semiconductor device, such as a memory device. A heat conducting layer 304 is shown coupled to a bulk portion 302. In one example, the bulk portion 302 includes silicon. In one example, the bulk portion 302 includes a carrier wafer. Carrier wafers may differ from other semiconductor wafers in that they do not contain circuitry for electrical devices. In one example, the bulk portion 302 includes a lower grade silicon than device grade silicon.

In one example, the heat conducting layer 304 includes a material having a lateral thermal conductivity higher than silicon. In one example, the heat conducting layer 304 includes a metal, such as copper with a high thermal conductivity. Copper possesses good thermal conductivity, however, it is relatively expensive.

In one example, the heat conducting layer 304 includes a material having a lateral thermal conductivity that is different than a vertical thermal conductivity. In one example, the heat conducting layer 304 includes carbon. In one example, the heat conducting layer 304 includes graphite. In one example, the heat conducting layer 304 includes graphene. In one example, the heat conducting layer 304 includes carbon nanotubes. In one example, the heat conducting layer 304 includes carbon particles suspended in an organic matrix. One example includes graphite particles within a polymer matrix. A graphite/polymer composite layer includes an advantage of ease of lamination to the bulk portion 302.

Graphite is relatively inexpensive, and exhibits high anisotropic heat conduction laterally. Using graphite provides an advantage of easily spreading heat from any local hot spots, which reduces thermal stress over high heat components within an adjacent electronic device as described in more detail below. In examples described below, vertical thermal conductivity in graphite is less necessary because of other structures in a vertical direction that slow heat transfer in the vertical direction.

In FIG. 3A, the heat conducting layer 304 is laminated to the bulk portion 302. In FIG. 3B, a bonding layer 306 is included for subsequent lamination to additional components. One example of a bonding layer includes an adhesive, although other bonding technologies are also within the scope of the invention. In one example, the combination of the heat conducting layer 304 and the bulk portion 302 define a heat spreader die 310.

In FIG. 3C, a first die 326 is shown coupled to a second die 322.

Similar to the discussion of FIG. 3A, in one example, the first die and second die 326, 322 are individual dies. In one example, the first die and second die 326, 322 are included in wafers at a wafer level as illustrated in FIGS. 2A and 2B. In one example, the first die 326 includes a semiconductor die, such as a memory die or a processor die. In one example, the second die 322 includes a logic die, or redistribution circuitry die.

In FIG. 3C, the first die 326 is shown coupled to a second die 322 with a first active surface 328 coupled towards a second active surface 327 of the second die 322. The first die 326 includes a backside 329 opposite the first active surface 328. A first bond pad 325 on the first die 326 is shown coupled to a second bond pad 323 on the second die 322. In one example, the first bond pad 325 is coupled to the second bond pad 323 using hybrid bonding, which includes a detectable dielectric bonding layer in the final bond structure. In one example, the first bond pad 325 is coupled to the second bond pad 323 using fusion bonding, which includes a detectable interface in the final bond structure. Although hybrid bonding and fusion bonding are used as examples, the invention is not so limited. Other bonding technologies such as solder are also possible. Hybrid bonding and fusion bonding include advantages such as higher connection density and low stack height.

FIGS. 3C and 3D further include a via segment 324. In one example, the via segment 324 is used in later processing to form a through silicon via (TSV) that passes from one side of the second die 322 to the other.

In FIG. 3D, the backside 329 of the first die 326 is thinned to a new surface 332. Thinning the backside provides a number of features. One example includes improved heat dissipation from devices formed in active surfaces 328 and 327. Another advantage includes smaller, thinner final devices.

In FIG. 3E, the heat spreader die 310 (e.g., comprising the bulk portion 302, the heat conducting layer 304, and the bonding layer 306) is coupled to the thinned backside surface 332 of the first die 326. Although FIG. 3E illustrated the thinned first die 326, the invention is not so limited. In other examples, the heat spreader die 310 is coupled to an unthinned backside 329 of the first die 326. In the example of FIG. 3E, the bonding layer 306 provides the attachment mechanism between the heat spreader die 310 and the first die 326. In the example of FIG. 3E, the bonding layer 306 forms a direct interface 342 with the first die 326. In other examples, the heat spreader die 310 forms a direct interface with the first die 326.

FIG. 3E further shows a second die backside 347 of the second die 322. A thickness between a heat spreader die backside 344 and the second die backside 347 is indicated by dimension 346. FIG. 3F shows thinning of the second die backside 347, and thinning of the heat spreader die backside 344, resulting in final device dimension 354. After thinning, the via segment 324 is coupled to a bottom pad 358, forming a TSV 359. The TSV 359 allows communication between additional circuitry such as a package, interposer, or a circuit board and the first die 326.

FIG. 3F shows one example of a final semiconductor device 350.

In one example the semiconductor device 350 has been singulated after wafer level processing as described in examples above, although the invention is not so limited. The semiconductor device 350 provides a number of advantages. The final device dimension 354 is thinner than many two die stack devices due to various thinning processes described above. Inclusion of the heat spreader die 310 provides the heat conducting layer 304 adjacent to active surface of the first die 326. The heat conducting layer 304 provides hot spot heat spreading in a lateral direction within the heat conducting layer 304, which improves performance of the first die 326 and reduces a risk of damage due to local overheating. The bulk portion 302 of the heat spreader die 310 provides additional mechanical stiffness and adds strength to the semiconductor device 350, which reduces a risk of handling damage during manufacturing.

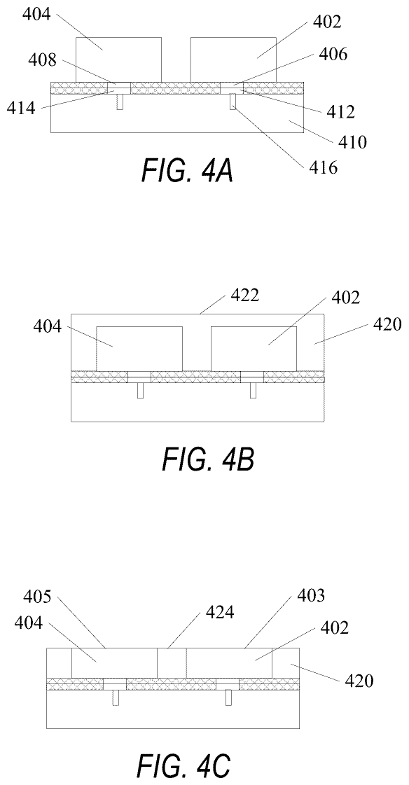

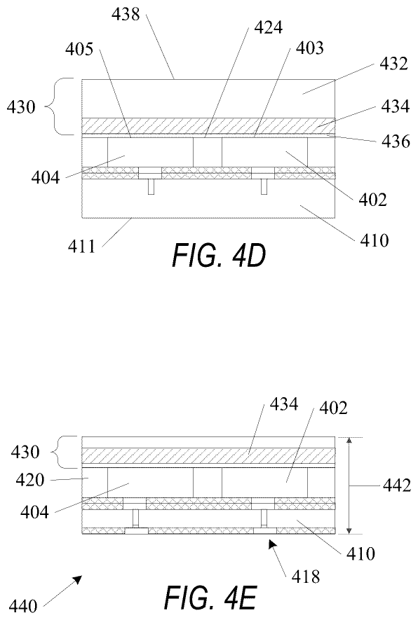

FIGS. 4A-4E show selected stages in manufacturing of another example semiconductor device. In FIG. 4A, a first chiplet 402 and a second chiplet 404 are coupled to a lower die 410. In one example, the first and second chiplets 402 and 404 are coupled to a lower device die that is integrated in a lower wafer. In an example, the first and second chiplets 402 and 404 can comprise respective memory devices or memory dies, such as DRAM dies. As noted above, processing at a wafer level provides a number of advantages such as high volume production and reduced cost.

Examples of the first and second chiplets 402 and 404 include memory chiplets, controller chiplets, etc. One of ordinary skill in the art, having the benefit of the present disclosure, will recognize that chiplets may alternately be referred to as dies. Similarly to examples described above, in one example the lower die 410 includes a logic die. A first bond pad 406 of the first chiplet 402 is coupled to a second bond pad 412 of the lower die 410. A third bond pad 408 of the second chiplet 404 is coupled to a fourth bond pad 414 of the lower die 410. Similarly to examples described above, coupling technology examples include, but are not limited to, hybrid bonding, fusion bonding, etc. One or more via segments 416 are shown that are later used to form TSVs.

In FIG. 4B an encapsulant 420 is applied, and encapsulates the first chiplet 402 and the second chiplet 404. Examples of encapsulants 420 include polymer encapsulants, such as resin, and may include one or more filler materials within a polymer matrix. An encapsulant backside 422 is shown after encapsulation, and above the first chiplet 402 and the second chiplet 404. In FIG. 4C, the encapsulant backside 422 has been thinned, and thinned encapsulant backside 424 is now parallel planar with a first backside 403 of the first chiplet 402, and a second backside 405 of the second chiplet 404. In one example, the first chiplet 402 and the second chiplet 404 are also thinned in FIG. 4C, however, the invention is not so limited.

In FIG. 4D, a heat spreader die 430, such as can be similar to the heat spreader die 310, is shown coupled to the first and second backsides 403 and 405 of the first and second chiplets 402 and 404, respectively. Because of the thinning operation in FIG. 4C, the heat spreader die 430 also forms an interface with the thinned encapsulant backside 424. Similarly to examples described above, in FIG. 4D, the heat spreader die 430 includes a heat conducting layer 434 and a bulk portion 432. In the example of FIG. 4D, a bonding layer 436 is further included, however, the invention is not so limited.

FIG. 4E shows thinning of a lower die backside 411, and thinning of a heat spreader die backside 438, relative to the example of FIG. 4D, resulting in final device thickness dimension 442. After thinning, the via segment 416 is coupled to a bottom pad, forming a TSV 418. As described above, the TSV 418 allows communication between additional circuitry such as a package, interposer, or a circuit board and the first and second chiplets 402 and 404.

FIG. 4E shows one example of a final semiconductor device 440.

In one example, the semiconductor device 440 has been singulated after wafer-level processing as described in examples above, although the invention is not so limited. Similarly to examples describe above, the semiconductor device 440 provides a number of advantages. The final device thickness dimension 442 is thinner relative to other devices, which is desirable to fit into ever smaller electronic devices, such as smart watches, etc. Inclusion of the heat spreader die 430 provides the heat conducting layer 434 adjacent to active surfaces of the first and second chiplets 402 and 404. The heat conducting layer 434 provides hot spot heat spreading in a lateral direction within the heat conducting layer 434, which improves performance of the first and second chiplets 402 and 404 and reduces a risk of damage due to local overheating. The bulk portion 432 of the heat spreader die 430 provides additional mechanical stiffness and adds strength to the semiconductor device 440, which reduces a risk of handling damage during manufacturing.

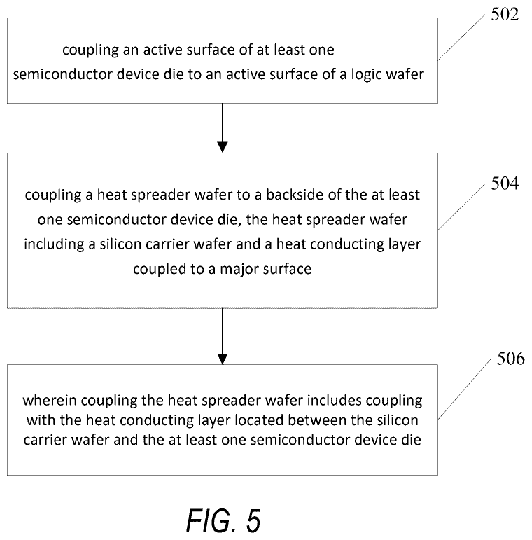

FIG. 5 shows an example flow diagram of a method of manufacture. In operation 502, an active surface of at least one semiconductor device die is coupled to an active surface of a logic wafer. In one example, an active surface of a semiconductor device wafer is coupled to an active surface of a logic wafer. In operation 504, a heat spreader wafer is coupled to a side surface (e.g., a backside) of the at least one semiconductor device die, the heat spreader wafer including a silicon carrier wafer and a heat conducting layer coupled to a major surface. In operation 506, coupling the heat spreader wafer to the die can optionally include coupling with the heat conducting layer located between the silicon carrier wafer and the at least one semiconductor device die.

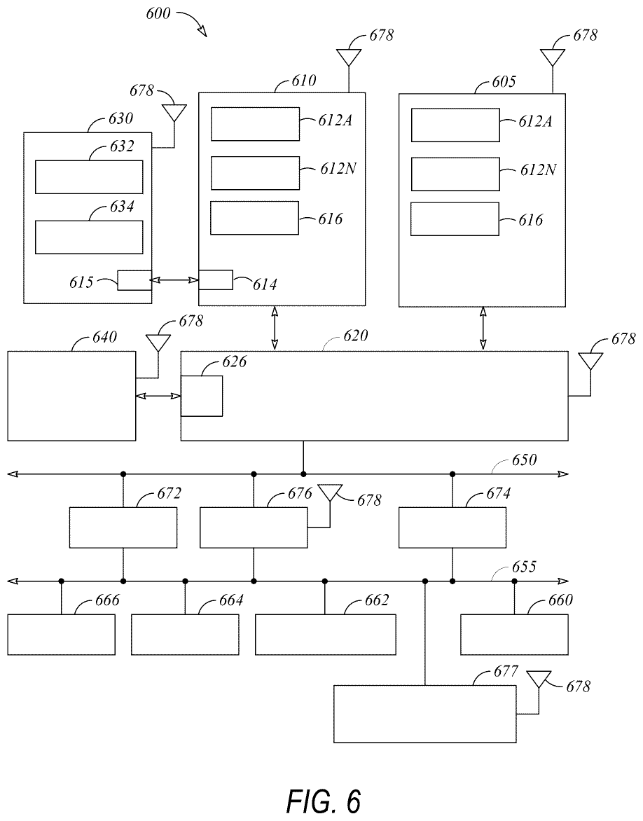

FIG. 6 illustrates a system level diagram, depicting an example of an electronic device (e.g., system) that may include semiconductor devices and/or methods described above. In one embodiment, system 600 includes, but is not limited to, a desktop computer, a laptop computer, a netbook, a tablet, a notebook computer, a server, a workstation, a cellular telephone, a mobile computing device, a smart phone, an artificial intelligence (AI) device or any other type of computing device. Various components of the system 600 can optionally be implemented using one or more chiplets.

At least one processor 610 is shown. The example of FIG. 6 shows a first processor 610 and a subsequent processor 605. In one example, processor 610 has one or more processor cores 612 and 612N, where 612N represents the Nth processor core inside processor 610. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some examples, processor 610 has a cache memory 616 to cache instructions and/or data for system 600.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, an interface for wireless antenna 678 operates in accordance with, but is not limited to, the IEEE 802.11 standard and its related family, Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In some embodiments, memory 630 includes a memory controller 615, which is operable to perform functions that enable the processor 610 to access and communicate with memory 630.

In one example, chipset 620 enables processor 610 to connect to other elements in system 600. In some examples, interfaces between components operate in accordance with a PtP communication protocol. In other embodiments, a different interconnect may be used.

In some embodiments, chipset 620 is operable to communicate with processor 610, 605N, display device 640, and other devices, including a bus bridge 672, a smart TV 676, I/O devices 674, nonvolatile memory 660, a storage medium (such as one or more mass storage devices) 662, a keyboard/mouse 664, a network interface 666, and various forms of consumer electronics 677 (such as a watch, smart phone, tablet etc.), etc. Chipset 620 may also be coupled to a wireless antenna 678 to communicate with any device configured to transmit and/or receive wireless signals.

Chipset 620 connects to display device 640 via interface 626. Display device 640 may be, for example, a liquid crystal display (LCD), a light emitting diode (LED) array, an organic light emitting diode (OLED) array, or any other form of visual display device. In some embodiments of the example system, processor 610 and chipset 620 are merged into a single system on a chip (SOC). In addition, chipset 620 connects to one or more buses 650 and 655 that interconnect various system elements, such as I/O devices 674, nonvolatile memory 660, storage medium 662, a keyboard/mouse 664, and network interface 666. Buses 650 and 655 may be interconnected together via a bus bridge 672.

In one embodiment, mass storage device 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612. Any one or more of the blocks can be integrated on or using a chiplet-based architecture.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

To better illustrate the method and apparatuses disclosed herein, a non-limiting list of embodiments is provided here:

Example 1. A semiconductor device, comprising: at least one semiconductor die, including an active surface coupled adjacent to an active surface of a logic die; a heat spreader die coupled to a backside of the at least one semiconductor die, including; a silicon carrier die; and a heat conducting layer coupled between the silicon carrier die and the at least one semiconductor die, the heat conducting layer having a lateral thermal conductivity higher than silicon.

Example 2. The semiconductor device of example 1, wherein the active surface of the at least one semiconductor die is electrically coupled to the active surface of the logic die with a hybrid bond.

Example 3. The semiconductor device of example 1, wherein the active surface of the at least one semiconductor die is electrically coupled to the active surface of the logic die with a fusion bond.

Example 4. The semiconductor device of example 1, wherein the heat conducting layer includes carbon.

Example 5. The semiconductor device of example 4, wherein the carbon in the heat conducting layer includes graphite.

Example 6. The semiconductor device of example 5, wherein the graphite in the heat conducting layer includes graphite particles in a polymer matrix.

Example 7. The semiconductor device of example 1, wherein the heat conducting layer includes copper.

Example 8. The semiconductor device of example 1, further including a bonding layer between the heat conducting layer and the at least one semiconductor die.

Example 9. The semiconductor device of example 1, wherein the at least one semiconductor die includes a memory die.

Example 10. A memory device, comprising: one or more semiconductor dies, each of the one or more semiconductor dies including an active surface coupled adjacent to an active surface of a logic die, wherein the logic die extends to a width greater than a width of the one or more semiconductor dies; an encapsulant surrounding lateral sides of the one or more semiconductor dies; a heat spreader die coupled to a backside of the one or more semiconductor dies, including; a silicon carrier die; and a heat conducting layer coupled between the silicon carrier die and the one or more semiconductor dies, the heat conducting layer having a lateral thermal conductivity higher than silicon.

Example 11. The memory device of example 10, wherein the heat conducting layer includes graphite.

Example 12. The memory device of example 11, wherein the graphite in the heat conducting layer includes graphite particles in a polymer matrix.

Example 13. The memory device of example 10, wherein the heat conducting layer includes copper.

Example 14. The memory device of example 10, further including a bonding layer between the heat conducting layer and the one or more semiconductor dies.

Example 15. The memory device of example 10, wherein the one or more semiconductor dies comprise one or more respective chiplets, and wherein the active surface of the logic die comprises an interposer configured to receive the one or more respective chiplets.

Example 16. A method of forming a semiconductor device, comprising: coupling an active surface of at least one semiconductor device die to an active surface of a logic wafer; coupling a heat spreader wafer to a backside of the at least one semiconductor device die, the heat spreader wafer including; a silicon carrier wafer; and a heat conducting layer coupled to a major surface of the silicon carrier wafer, the heat conducting layer having a lateral thermal conductivity higher than silicon; wherein coupling the heat spreader wafer includes coupling with the heat conducting layer located between the silicon carrier wafer and the at least one semiconductor device die.

Example 17. The method of example 16, further including encapsulating the at least one semiconductor device die to form an encapsulated semiconductor device die.

Example 18. The method of example 17, further including thinning a backside of the encapsulated semiconductor device die to expose the at least one semiconductor device die.

Example 19. The method of example 16, wherein the at least one semiconductor device die is included in a semiconductor device wafer that includes multiple semiconductor dies formed in a continuous silicon wafer.

Example 20. The method of example 19, further including thinning a backside of the multiple semiconductor dies formed in the continuous silicon wafer.

Example 21. The method of example 20, further including backside thinning of the silicon carrier wafer.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A semiconductor device, comprising:
at least one semiconductor die, including an active surface coupled adjacent to an active surface of a logic die;
a heat spreader die coupled to a backside of the at least one semiconductor die, including;
a silicon carrier die; and
a heat conducting layer coupled between the silicon carrier die and the at least one semiconductor die, the heat conducting layer having a lateral thermal conductivity higher than silicon.

2. The semiconductor device of claim 1, wherein the active surface of the at least one semiconductor die is electrically coupled to the active surface of the logic die with a hybrid bond.

3. The semiconductor device of claim 1, wherein the active surface of the at least one semiconductor die is electrically coupled to the active surface of the logic die with a fusion bond.

4. The semiconductor device of claim 1, wherein the heat conducting layer includes carbon.

5. The semiconductor device of claim 4, wherein the carbon in the heat conducting layer includes graphite.

6. The semiconductor device of claim 5, wherein the graphite in the heat conducting layer includes graphite particles in a polymer matrix.

7. The semiconductor device of claim 1, wherein the heat conducting layer includes copper.

8. The semiconductor device of claim 1, further including a bonding layer between the heat conducting layer and the at least one semiconductor die.

9. The semiconductor device of claim 1, wherein the at least one semiconductor die includes a memory die.

10. A memory device, comprising:
one or more semiconductor dies, each of the one or more semiconductor dies including an active surface coupled adjacent to an active surface of a logic die, wherein the logic die extends to a width greater than a width of the one or more semiconductor dies;
an encapsulant surrounding lateral sides of the one or more semiconductor dies;
a heat spreader die coupled to a backside of the one or more semiconductor dies, including;
a silicon carrier die; and
a heat conducting layer coupled between the silicon carrier die and the one or more semiconductor dies, the heat conducting layer having a lateral thermal conductivity higher than silicon.

11. The memory device of claim 10, wherein the heat conducting layer includes graphite.

12. The memory device of claim 11, wherein the graphite in the heat conducting layer includes graphite particles in a polymer matrix.

13. The memory device of claim 10, wherein the heat conducting layer includes copper.

14. The memory device of claim 10, further including a bonding layer between the heat conducting layer and the one or more semiconductor dies.

15. The memory device of claim 10, wherein the one or more semiconductor dies comprise one or more respective chiplets, and wherein the active surface of the logic die comprises an interposer configured to receive the one or more respective chiplets.

16. A method of forming a semiconductor device, comprising:
coupling an active surface of at least one semiconductor device die to an active surface of a logic wafer;
coupling a heat spreader wafer to a backside of the at least one semiconductor device die, the heat spreader wafer including;
a silicon carrier wafer; and
a heat conducting layer coupled to a major surface of the silicon carrier wafer, the heat conducting layer having a lateral thermal conductivity higher than silicon;
wherein coupling the heat spreader wafer includes coupling with the heat conducting layer located between the silicon carrier wafer and the at least one semiconductor device die.

17. The method of claim 16, further including encapsulating the at least one semiconductor device die to form an encapsulated semiconductor device die.

18. The method of claim 17, further including thinning a backside of the encapsulated semiconductor device die to expose the at least one semiconductor device die.

19. The method of claim 16, wherein the at least one semiconductor device die is included in a semiconductor device wafer that includes multiple semiconductor dies formed in a continuous silicon wafer.

20. The method of claim 19, further including thinning a backside of the multiple semiconductor dies formed in the continuous silicon wafer.

21. The method of claim 20, further including backside thinning of the silicon carrier wafer.
